(19) United States
(12) Patent Application Publication
(10) Pub. No.: US 2015/0024584 A1
(43) Pub. Date: Jan. 22, 2015

(54) METHODS FOR FORMING INTEGRATED CIRCUITS WITH REDUCED REPLACEMENT METAL GATE HEIGHT VARIABILITY

(71) Applicant: GLOBAL FOUNDRIES, INC., Grand Cayman (KY)

(72) Inventors: Gabriel Padron Wells, Saratoga Springs, NY (US); Yuan-Hung Liu, Cohoes, NY (US); Kristina Trevino, Austerlitz, NY (US); Chang Ho Maeng, Clifton Park, NY (US); Taejoon Han, Clifton Park, NY (US)

(21) Appl. No.: 13/943,909

(22) Filed: Jul. 17, 2013

(51) Int. Cl. H01L 21/28

(52) U.S. Cl. CPC H01L 21/28
USPC 438/589

(57) ABSTRACT

Methods for fabricating integrated circuits with reduced replacement metal gate height variability are provided. In an embodiment, a method includes providing a semiconductor substrate with a fin supported thereon and forming a conformal material layer overlying the fin and the semiconductor substrate. A trench is etched within the conformal material layer such that the trench exposes a surface of the fin and the semiconductor substrate. A conductive gate structure is formed within the trench, the conformal material layer is removed, and spacers are formed on the sidewalls of the conductive gate.

### TECHNICAL FIELD

The technical field generally relates to methods for fabricating integrated circuits, and more particularly relates to methods for fabricating integrated circuits with reduced replacement metal gate height variability.

### BACKGROUND

Transistors such as metal oxide semiconductor field effect transistors (MOSFETs) or simply field effect transistors (FETs) or MOS transistors are important building blocks of the vast majority of semiconductor integrated circuits (ICs). An FET includes source and drain regions between which a current can flow through a channel under the influence of a bias applied to a gate electrode that overlies the channel. Some semiconductor ICs, such as high performance microprocessors, can include millions of FETs. For such ICs, decreasing transistor size and thus increasing transistor density has traditionally been a high priority in the semiconductor manufacturing industry. Transistor performance, however, must be maintained even as the transistor size decreases.

A FINFET is a type of transistor that lends itself to the goals of reducing transistor size while maintaining transistor performance. As illustrated in FIG. 1, the FINFET 10 is a non-planar, three dimensional transistor formed in part in a thin fin 12 that extends upwardly from a semiconductor substrate 14. FIG. 1 shows only one gate and two fins for simplicity although typically an integrated circuit can have thousands of fins and gates. The semiconductor substrate may be a bulk silicon wafer from which the fin structures are formed or may be a silicon-on-insulator (SOI) wafer disposed on a support substrate. The SOI wafer includes a silicon oxide layer and a silicon-containing material layer overlying the silicon oxide layer. The fin structures are formed from the silicon-containing material layer. The fin structures are typically formed using conventional photolithographic or anisotropic etching processes (e.g., reactive ion etching (RIE) or the like). A vertical gate 16 is disposed over the fin such that the two vertical sidewalls 18 of the fin form the channel of the transistor.

Replacement metal gate (RMG) processing is often used during FinFET formation. FIGS. 2-5 illustrate a conventional method for forming a FinFET integrated circuit using RMG processing. FIG. 2 lies along axis y₁-y₁ illustrated in FIG. 1 and shows two fins 12 supported by a semiconductor substrate 14. An insulation layer 20 isolates the fins from each other. An amorphous silicon layer 22 is deposited overlying the fins 12 and the insulation 20. A portion of the amorphous silicon layer is removed, typically by chemical mechanical planarization (CMP), to obtain a planarized surface on the amorphous silicon. With CMP, the planarized surface of the amorphous silicon layer 22 results in approximately a 10 nanometer (nm) surface variance. After CMP, typically a silicon nitride layer 21 is deposited on the amorphous silicon layer 22.

Next, referring to FIG. 3, the amorphous silicon and the silicon nitride layer are patterned into dummy gates 24 and silicon nitride caps 30 thereon, spacers 26 are formed on sidewalls of the dummy gates, and an oxide fill layer 28 is deposited overlying the dummy gates and spacers. FIG. 3 is taken through axis x₁-x₁ illustrated in FIG. 1. At this point, another CMP process is required to planarize the oxide fill layer. The CMP process can add an additional approximately 8-9 nm variance to the surface of the oxide fill. The silicon nitride caps 30 and the dummy gates 24 then are removed.

The trenches left by the removal of the dummy gates and silicon nitride caps are then filled by an RMG process. FIG. 4 shows replacement metal gates overlying the fins and along axis x₂-x₂, as illustrated in FIG. 1, and FIG. 5 shows the same replacement metal gates taken along axis x₁-x₁. A gate dielectric layer 32 typically is deposited in the trenches, followed by various barrier metal layers and/or work function metal layers 34, and finally a conductive metal gate material 36, such as tungsten. A CMP process is performed to remove any overfill.

This additional CMP process can add another approximately 10 nm surface variance, resulting in an overall surface of variance of approximately 28-29 nm when only about +5 nm variance should be tolerated. Dishing between features may also be an issue. Thus, this conventional replacement metal gate protocol may not be able to comply with gate height uniformity requirements for successful development of advanced technology nodes in the semiconductor industry, such as those requiring +5 nm deviation from target features. Generally, CMP processing provides approximately 7 nm surface variance if a stop layer is utilized and approximately 10 nm surface variance if no stop layer is utilized.

Accordingly, it is desirable to provide methods for fabricating integrated circuits with reduced replacement height variability. In addition, it is desirable to provide methods for fabricating integrated circuits that provide flexibility in replacement metal gate processing. Furthermore, other desirable features and characteristics will become apparent from the subsequent detailed description and the appended claims, taken in conjunction with the accompanying drawings and this background.

### BRIEF SUMMARY

Methods for fabricating integrated circuits with reduced replacement metal gate height variability are provided. In an embodiment, a method includes providing a semiconductor substrate with a fin supported thereon and forming a conformal material layer overlying the fin and the semiconductor substrate. A trench is etched within the conformal material layer such that the trench exposes a surface of the fin and the semiconductor substrate. A conductive gate structure is formed within the trench, the conformal material layer is removed, and spacers are formed on the sidewalls of the conductive gate.

In accordance with another embodiment, a method of fabricating an integrated circuit includes providing a first set of fins and a second set of fins. The first set of fins and the second set of fins are supported by a semiconductor substrate. A conformal material layer is deposited overlying the first set of fins and the second set of fins and the semiconductor substrate. A first trench and a second trench are etched in the conformal material layer such that the first trench exposes surfaces of the first set of fins and the second trench exposes surfaces of the second set of fins. A first gate dielectric layer is deposited in the second trench to a first thickness and a second gate dielectric layer is deposited in the first trench to a second thickness, where the first thickness and the second thickness are not equal. A conductive gate is formed overlying the first gate dielectric layer and overlying the second gate dielectric layer. The conformal material layer is removed and spacers are formed on the sidewalls of the conductive gates.

In accordance with a further embodiment, a method of fabricating an integrated circuit includes providing a semiconductor substrate with a plurality of fins supported thereon. An insulation is formed between the plurality of fins and a conformal material layer is spin-coated overlying the insulation and the plurality of fins. A plurality of trenches is etched into the conformal material layer and the insulation such that the plurality of trenches exposes surfaces of the plurality of fins and the semiconductor substrate. A gate dielectric layer is formed within the trenches and a barrier metal layer is deposited overlying the gate dielectric layer. A work function layer is formed overlying the gate dielectric layer and a conductive gate is deposited overlying the work function layer. The gate dielectric layer, the barrier metal layer, the work function layer, and the conductive gate are recessed within the trench and an insulating cap is formed overlying the conductive gate and within the trench. The conformal material layer is removed and spacers are formed on the sidewalls of the conductive gate structure.

### BRIEF DESCRIPTION OF THE DRAWINGS

The various embodiments will hereinafter be described in conjunction with the following drawing figures, wherein like numerals denote like elements, and wherein:

FIG. 1 is a perspective view of a single-gate FinFET as known in the prior art;

FIGS. 2-5 illustrate steps for forming a FinFET as known in the prior art. In this regard:

FIG. 2 is a cross-sectional view taken along axis y₁-y₁ of FIG. 1;

FIG. 3 is a cross-sectional view taken along axis x₁-x₁ of FIG. 1;

FIG. 4 is a cross-sectional view taken along axis x₂-x₂ of FIG. 1;

FIG. 5 is a cross-sectional view taken along axis x₁-x₁ of FIG. 1;

FIGS. 6-12 illustrate methods for forming an integrated circuit in accordance with an exemplary embodiment. In this regard:

FIG. 6 is a cross-sectional view taken along axis y₁-y₁ of FIG. 1;

FIG. 7 is a cross-sectional view taken along axis x₂-x₂ of FIG. 1;

FIGS. 8-11 are cross-sectional views taken along axis x₂-x₂ of FIG. 1; and

FIG. 12 is a cross-sectional view taken along axis x₁-x₁ of FIG. 1.

### DETAILED DESCRIPTION

The following detailed description is merely exemplary in nature and is not intended to limit the various embodiments or the application and uses thereof. Furthermore, there is no intention to be bound by any theory presented in the preceding background or the following detailed description.

Various embodiments of a method for fabricating integrated circuits with reduced replacement metal gate height variability are provided. The method eliminates the need to utilize numerous CMP processing steps to drive planarization and, thus, reduces surface variance and unwanted gate height variability. In this regard, the method reduces the cost of the overall device manufacturing. In addition, the method places the RMG development before spacer formation thus allowing device conception to be built around a gate reference framework (pseudo-gate first approach) rather than a dummy gate reference framework. Further, while conventional methods create stand-alone gate features, the method contemplated herein utilizes trenches for forming the RMGs. Patterning of trench features feasibly reduces the effective aspect ratio of tight pitch patterns/structures, thus simplifying corresponding schemes to enable consistent and reproducible outputs. Trench patterning also can have an overall positive effect, making pertinent lithography processing more reliable to complete pattern transfer sequences (line resist vs. space resist lithography scheme).

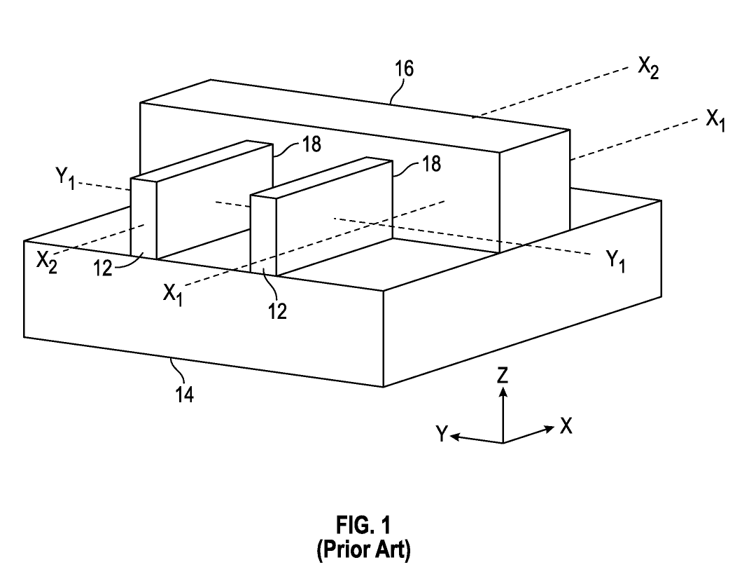

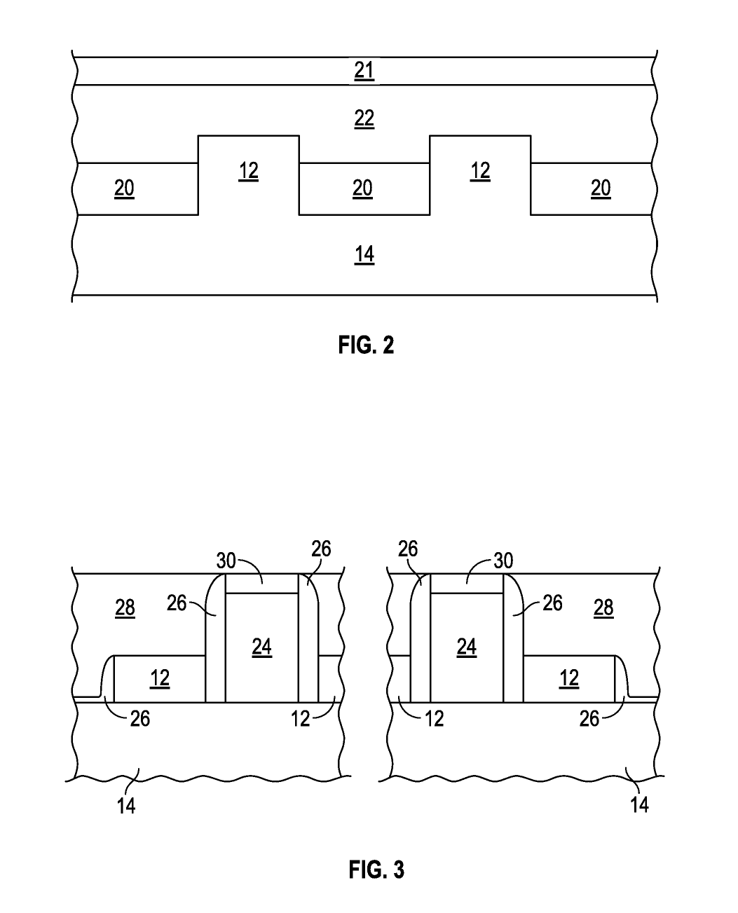

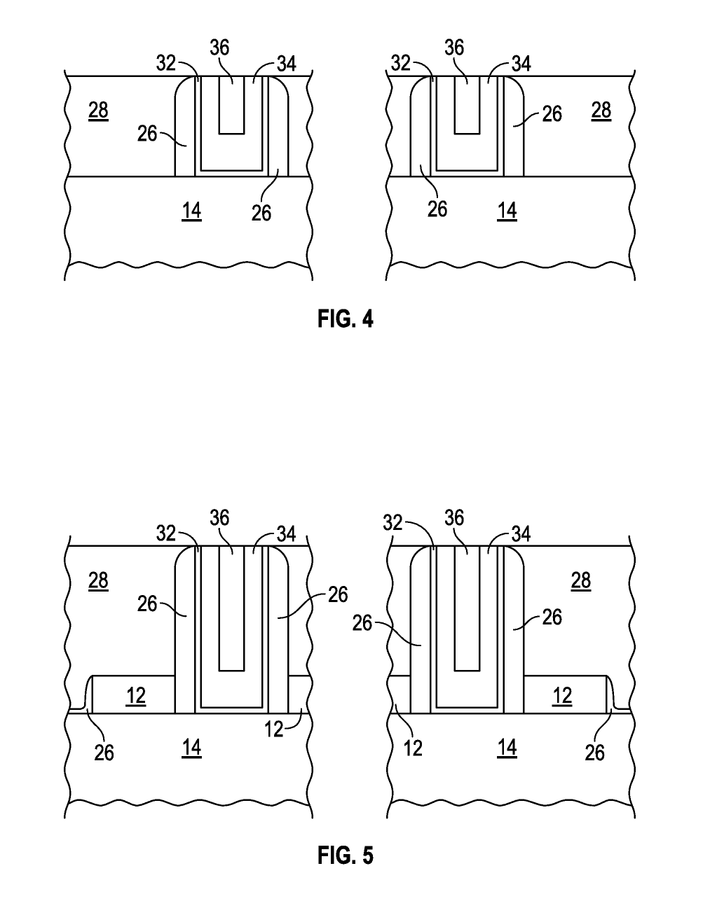

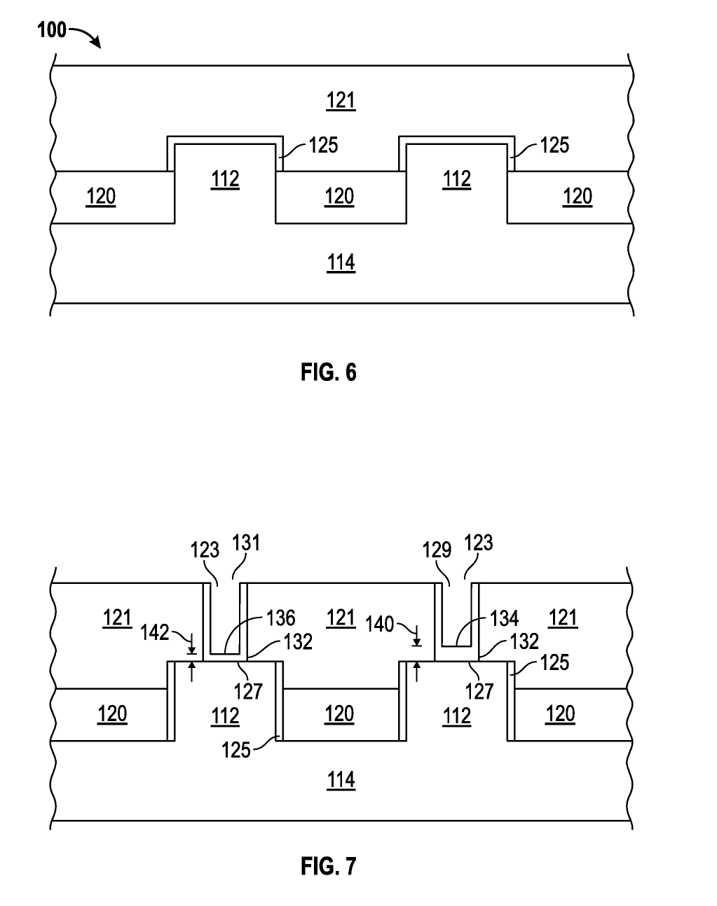

A method for fabricating an integrated circuit (IC) 100 with reduced replacement metal gate height variability is illustrated in FIGS. 6-12. Various steps in the manufacture of ICs are well known and so, in the interest of brevity, many conventional steps will only be mentioned briefly herein or will be omitted entirely without providing the well-known process details. A portion of IC 100 as shown in FIG. 6 is at an early stage of fabrication. The method begins by providing fins 112 supported by a semiconductor substrate 114, as illustrated in FIG. 6. FIG. 6 is taken along the y₁-y₁ axis of FIG. 1. While only two fins are shown, it will be appreciated that the number of fins supported by the semiconductor substrate will depend on the application of the integrated circuit.

The fins 112 are supported by a bulk semiconductor substrate 114 that is formed of a semiconductor material. In an exemplary embodiment, the bulk semiconductor substrate 114 is a bulk silicon substrate and the semiconductor material includes silicon. For example, the bulk silicon substrate can be formed from relatively pure silicon, silicon admixed with germanium or carbon, or silicon admixed with some other semiconductor material(s) commonly used in the fabrication of integrated circuits. Alternatively, the semiconductor material of the bulk semiconductor substrate 114 can be germanium, gallium arsenide, or the like. The semiconductor material need not be doped, although it may be very lightly doped as either N-type or P-type, without impacting the manufacturing process described herein. Alternatively the fins 112 can be supported by a silicon-on-insulator (SOI) wafer disposed on a support substrate. The SOI wafer includes a silicon oxide layer and a silicon-containing material layer overlying the silicon oxide layer. The fin structures are formed from the semiconductor material.

An insulator 120 overlies the semiconductor substrate 114 between the fins to electrically isolate the fins 112. As used herein, the term “overlie” means to lie directly on or to lie over such that an intervening material lies there between. For example, insulator 120 may lie directly on semiconductor substrate 114 or may overlie the semiconductor substrate such that a dielectric layer or other layer lies between the insulator 120 and the semiconductor substrate 114. The insulator 120 is, for example, a silicon oxide layer.

A conformal material layer 121 is formed overlying the insulator 120 and the fins 112. The conformal layer is of any material that has an etch selectivity to the semiconductor substrate and to a masking material used to etch the conformal material, as discussed in more detail below, and forms a highly conformal, highly planarized layer when deposited, such as by spin coating. In one embodiment, the conformal material layer 121 has a surface variability of no greater than 3 nm across the surface of the conformal material layer. In another embodiment, the conformal material layer 121 has a surface variability of less than 3 nm across the surface of the conformal material layer. An example of a suitable conformal material includes, but is not limited to DUO™ 248 available from Honeywell International, Inc. of Morristown, N.J. The conformal material layer 121 is formed overlying the insulator 120 and fins 112 by spin coating, roller coating, spraying, and the like. The conformal material layer may be deposited to a height suitable to accommodate a height of a metal gate. In an embodiment, the conformal material layer 121 is deposited to a thickness in the range of from about 50 nm to about 150 nm. In an optional embodiment, a protective layer 125 is formed overlying the fins before formation of the conformal material layer 121. The protective layer 125 serves to prevent fin erosion, which also becomes the area of the active channel, during trench patterning discussed below. The protective layer 125 includes a material that has an etch rate that is faster than an etch rate of the semiconductor material of the fins 112, such as, for example, silicon oxide. In one embodiment, the protective layer has a thickness in the range of from about 3 nm to about 15 nm.

Referring to FIG. 7, trenches 123 are etched into the conformal material layer 121 such that surfaces 127 of the fins 112 are exposed. FIG. 7 is taken along axis x₂-x₂ as illustrated in FIG. 1. The trenches have a width of about 20 nm to about 1000 nm. If the conformal material is Honeywell's DUO 248, the conformal material layer 121 can be etched with a plasma etch using, for example, a N₂/H₂/CH₄ chemistry.

In one embodiment, a gate dielectric material 132 is deposited within the trenches. The gate dielectric material 132 is a deposited insulator such as a silicon oxide, silicon nitride, any kind of high-dielectric constant (high-k) material, such as hafnium oxides, or the like. Deposited insulators can be deposited, for example, by chemical vapor deposition (CVD), atomic layer deposition (ALD), low pressure chemical vapor deposition (LPCVD), or plasma enhanced chemical vapor deposition (PECVD). In an alternative embodiment, as illustrated in FIG. 7, a mask (not shown), such as a photoresist is deposited overlying the conformal material layer 121 and within the trenches. The mask is patterned to expose a first set 129 of trenches 123. The gate dielectric material 132 is deposited within the first set 129 of trenches 123 to form a first gate dielectric 134. The mask then is removed from a second set 131 of trenches 123. The gate dielectric material again is deposited in the exposed trenches 123 to form a second gate dielectric 136. Because additional gate dielectric material is deposited on first gate dielectric 134 during the second deposition, first gate dielectric has a thickness, indicated by double-headed arrow 140, that is greater than a thickness, indicated by arrows 142, of second gate dielectric 136. The process of unmasking trenches and depositing gate dielectric material can continue to form any number of sets of gate dielectrics with varying thicknesses. Thus, short channel devices, long channel devices, and other devices of varying channel size can be fabricated on and in the integrated circuit with minimal processing. In one embodiment, the gate dielectrics have a thickness in the range of from about 1 to about 10 nm, although the actual thickness can be determined based on the application of the FinFETs in the integrated circuits being implemented. It will be appreciated that while FIG. 7 is described with first gate dielectric 134 and second gate dielectric 136 formed of the same material, it is contemplated herein that alternatively the first gate dielectric 134 and second gate dielectric 136 may be formed of different dielectric materials.

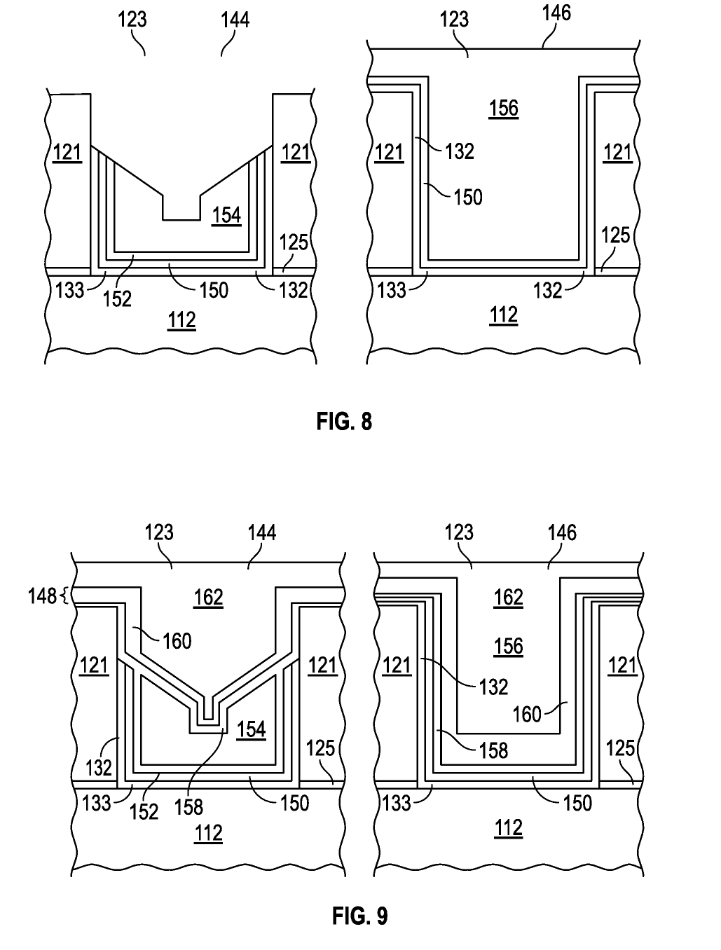

FIG. 8 is a close-up view of the two trenches illustrated in FIG. 7 with gate dielectric material 132 forming generally gate dielectrics 133 of any suitable thickness. The method continues with the formation of a metal gate of a p-channel FinFET (PFET) 144 and a metal gate of an n-channel FinFET (NFET) 146. In this regard, barrier metals are formed overlying the gate dielectrics 133. Metals suitable for use as barrier metals include those that prevent metal ions from the metal gate (to be discussed below) from migrating into the conformal material layer 121. In addition, the metals are selected for their ability to adhere to the metal gate and to the gate dielectric material 132. In an embodiment, a layer of titanium nitride 150 is formed within the trenches and overlying the gate dielectric material 132. The titanium nitride can be deposited, for example, by physical vapor deposition (PVD). The thickness of the titanium nitride layer 150, for example, is in the range of from about 1 nm to about 2 nm. Next, in an embodiment, a mask 156 is deposited and is patterned such that it remains overlying the nFET but exposing the pFET. The mask is, for example, a photoresist. Tantalum nitride is deposited overlying the titanium nitride in the exposed trenches 123 to form a tantalum nitride layer 152. The tantalum nitride layer is deposited, for example, by PVD. In an embodiment, the tantalum nitride layer 152 has a thickness in the range of from about 1 nm to about 2 nm. Another titanium nitride layer 154 is formed on the tantalum nitride layer 152 by depositing titanium nitride as described above. The titanium nitride layer 154 can be deposited to a thickness, for example, in the range of from about 3 nm to about 5 nm. Once formed, a portion of the barrier metals titanium nitride and tantalum nitride, along with the gate dielectric layer 132, are removed from the exposed trench (for pFET 144). The barrier metals are selectively removed by a chemistry such as BCO₃/Cl₂. If the gate dielectric layer 132 is, for example, hafnium oxide, it can be removed by a fluorocarbon chemistry, such as CF₄ or C₄F₆. Because the etching is anisotropic, the metals form a chamfered or “V” shape surface proximate to the opening of the pFET trench. The gate dielectric material 132 also is removed.

Referring to FIG. 9, after etching of the various metal layers and the gate dielectric, the mask 156 is removed. A tantalum nitride deposition is performed to globally form a tantalum nitride layer 158. In an embodiment, the tantalum nitride has a thickness in the range of from about 2 nm to about 4 nm. A work function material titanium aluminum then is deposited to form a titanium aluminum layer 160 overlying the tantalum nitride layer 158. TiAl effectively stabilizes device threshold voltage performance at a centering target of about 0.3V. In advanced semiconductor manufacturing, the ability to reliably control the threshold voltage parameter, according to specified layout designs, is important to guarantee effective device turn-on performance. The titanium aluminum layer can be deposited, for example, by ALD, and, in an embodiment, has a thickness in the range of from about 4 nm to about 7 nm. Following deposition of the titanium aluminum layer, a conductive metal gate 162 is deposited within the trench 123 of the pFET transistor 144 and the trench 123 of the nFET transistor 146 to fill the trenches. The conductive metal gate 162 can be formed of any suitable conductive metal such as, aluminum or, for example, tungsten. A CMP process is performed to remove the overburden overlying the conformal material layer 121.

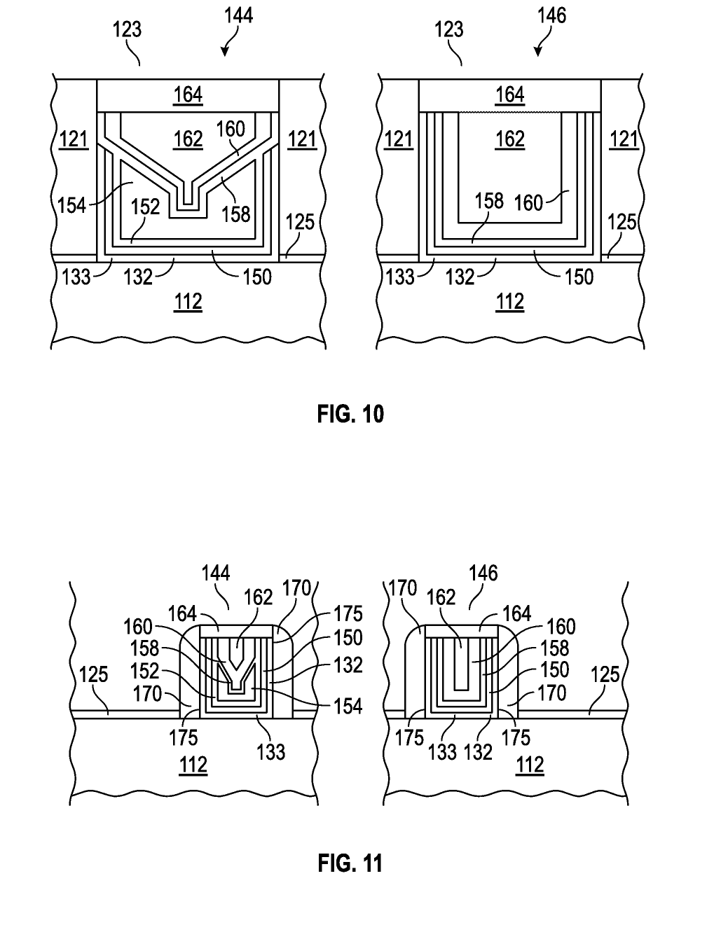

In an embodiment, as illustrated in FIG. 10, a portion of the conductive metal gate 162 is removed to provide space within the trenches 123 for an insulating cap (described below) to cover the metal gate. If the metal gate is tungsten, the tungsten can be etched by reactive ion etching (RIE) using a hydrofluoric acid chemistry. The work function and barrier metal layers are selectively removed by a chemistry such as, for example, BCO₃/Cl₂. An insulating cap-forming layer is deposited within the trenches 123. The insulating cap forming layer is of a material that has an etch rate that is less than the etch rate of the conformal material layer 121. In an embodiment, the insulating cap forming layer is formed of silicon nitride. Once deposited, the insulating cap forming layer is subjected to CMP to form an insulating cap 164 overlying the conductive metal gates 162 of both the pFET 144 and the nFET 146.

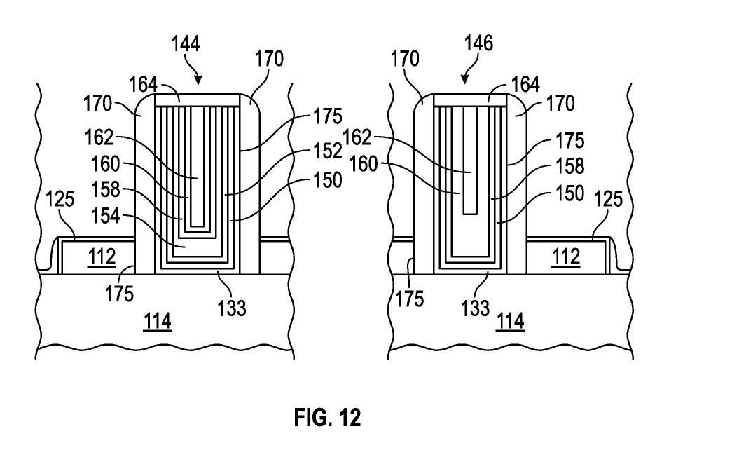

Next, referring to FIGS. 11 and 12, the conformal material layer 121 is removed, leaving conductive metal gates 162 as free-standing structures. FIG. 11 is taken along the x₂-x₂ axis and FIG. 12 is taken along the x₁-x₁ axis of FIG. 1. The conformal material layer 121 is removed, for example, by RIE in a N₂/H₂/diluted CH₄ chemistry. A spacer-forming material layer is conformally deposited on the sidewalls 175 of the conductive metal gates 162 and is anisotropically etched to form spacers 170. The spacer-forming material layer includes a material having an etch rate that is faster than an etch rate of silicon, such as, for example, silicon nitride. In one embodiment, the spacer-forming material is deposited to a thickness in the range of about 15 nm to about 25 nm.

Fabrication of the FinFET semiconductor devices may thereafter continue with further processing steps that can be performed to complete the fabrication the device, as are well-known in the art. Further steps conventionally include, for example, the formation of source and drain regions in the fins adjacent the metal gates, the formation of contacts (formed by depositing a photoresist material layer over an insulating layer, lithographic patterning, etching to form contact voids, and depositing a conductive material in the voids to form the contacts), and the formation of one or more patterned conductive layers across the device above the insulating layer, among many others. The subject matter disclosed herein is not intended to exclude any subsequent processing steps to form and test the completed FinFET semiconductor device as are known in the art. Furthermore, with respect to any of the process steps described above, one or more heat treating and/or annealing procedures can be employed after the deposition of a layer, as is commonly known in the art.

Accordingly, methods for fabricating integrated circuits with reduced replacement metal gate height variability are provided. The methods achieve gate height control by eliminating numerous CMP processing steps to drive planarization and, thus, can reduce surface variability up to 50 to 60%. In this regard, the methods reduce the cost of the overall device manufacturing. In addition, while conventional methods create stand-alone dummy gate features, the methods contemplated herein utilize trenches for forming the RMGs. Patterning of trench features reduces the effective aspect ratio of tight pitch patterns/structures, thus simplifying corresponding schemes to enable consistent and reproducible results. Trench patterning also can have an overall positive effect, making pertinent lithography processing more reliable to complete pattern transfer sequence (line resist vs. space resist lithography scheme). The methods contemplated herein thus will enable a more reliable patterning scheme to drive advanced semiconductor manufacturing on to the latest technology nodes (14 nm, 10 nm and beyond).

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention. It being understood that various changes may be made in the function and arrangement of elements described in an exemplary embodiment without departing from the scope of the invention as set forth in the appended claims.

What is claimed is:

1. A method of fabricating an integrated circuit, the method comprising:
providing a semiconductor substrate with a fin supported thereon;
forming a conformal material layer overlying the fin and the semiconductor substrate;
etching a trench within the conformal material layer such that the trench exposes a surface of the fin and the semiconductor substrate;
forming a conductive gate structure within the trench;
removing the conformal material layer; and
forming spacers on sidewalls of the conductive gate structure.

2. The method of claim 1, wherein forming the conductive gate structure comprises:
forming a gate dielectric layer within the trench;
depositing a first barrier metal overlying the gate dielectric layer;
depositing a second barrier metal overlying the first barrier metal;
forming a work function material layer overlying the second barrier metal; and
forming a metal gate overlying the work function material layer.

3. The method of claim 2, wherein forming the gate dielectric layer comprises forming a gate dielectric comprising hafnium oxide.

4. The method of claim 2, wherein depositing the first barrier metal comprises depositing the first barrier metal comprising titanium nitride and wherein depositing the second barrier metal comprises depositing the second barrier metal comprising tantalum nitride.

5. The method of claim 2, wherein forming the work function material layer comprises forming the work function material layer comprising titanium aluminum.

6. The method of claim 2, wherein forming the metal gate comprises forming the metal gate comprising tungsten.

7. The method of claim 1, wherein forming the conductive gate structure comprises:
forming a gate dielectric layer within the trench;
depositing a first layer of a first barrier metal overlying the gate dielectric layer;
depositing a layer of a second barrier metal overlying the first layer of the first barrier metal;
depositing a second layer of the first barrier metal overlying the layer of the second barrier metal;
removing a portion of the gate dielectric layer, the first layer of the first barrier metal, the layer of the second barrier metal, the second layer of the first barrier metal, and the gate dielectric layer from within the trench;
depositing a work function material layer within the trench; and
forming a metal gate overlying the work function material layer;

8. The method of claim 7, wherein forming the gate dielectric layer comprises forming a gate dielectric comprising hafnium oxide.

9. The method of claim 7, wherein depositing the first layer of the first barrier metal comprises depositing the first layer of the first barrier metal comprising titanium nitride and wherein depositing the layer of the second barrier metal comprises depositing the layer of the second barrier metal comprising tantalum nitride.

10. The method of claim 7, wherein depositing the work function material layer comprises forming the work function material layer comprising titanium aluminum.

11. The method of claim 7, wherein forming the metal gate comprises forming the metal gate comprising tungsten.

12. The method of claim 1, further comprising removing a portion of the conductive gate structure from the trench and forming an insulating cap overlying the conductive gate structure.

13. The method of claim 12, further comprising forming spacers on the sidewalls of the conductive gate structure.

14. A method of fabricating an integrated circuit, the method comprising:
providing a first set of fins and a second set of fins, wherein the first set of fins and the second set of fins are supported by a semiconductor substrate;
depositing a conformal material layer overlying the first set of fins and the second set of fins and the semiconductor substrate;
etching a first trench and a second trench in the conformal material layer such that the first trench exposes surfaces of the first set of fins and the second trench exposes surfaces of the second set of fins;
depositing a first gate dielectric layer in the second trench to a first thickness;
depositing a second gate dielectric layer in the first trench to a second thickness, where the first thickness and the second thickness are not equal;
forming a conductive gate overlying the first gate dielectric layer and overlying the second gate dielectric layer;
removing the conformal material layer; and
forming spacers on sidewalls of the conductive gates.

15. The method of claim 14, wherein the first gate dielectric layer and the second gate dielectric layer comprise the same material.

16. The method of claim 15, wherein the first gate dielectric layer and the second gate dielectric layer comprise hafnium oxide.

17. The method of claim 14, further comprising, before forming spacers, removing a portion of the conductive gates from the first trench and the second trench and forming insulating caps overlying the conductive gates.

18. The method of claim 14, wherein forming the conductive gate overlying the first gate dielectric layer and overlying the second gate dielectric layer comprises:
depositing a titanium nitride layer overlying the second gate dielectric layer;
depositing a tantalum nitride layer overlying the titanium nitride layer;
forming a titanium aluminum layer overlying the titanium nitride layer; and
forming a tungsten gate overlying the titanium aluminum layer.

19. The method of claim 14, wherein forming the conductive gate overlying the first gate dielectric layer and overlying the second gate dielectric layer comprises:
depositing a first titanium nitride layer overlying the first gate dielectric layer;
depositing a tantalum nitride layer overlying the first titanium nitride layer;
depositing a second titanium nitride layer overlying the tantalum nitride layer;
removing a portion of the first gate dielectric layer, the first titanium nitride layer, the tantalum nitride layer, and the second titanium nitride layer from within the second trench;
depositing a titanium aluminum layer within the second trench; and
forming a tungsten gate overlying the titanium aluminum layer.

20. A method of fabricating an integrated circuit, the method comprising:
providing a semiconductor substrate with a plurality of fins supported thereon;
forming an insulation between the plurality of fins;
spin coating a conformal material layer overlying the insulation and the plurality of fins;
etching a plurality of trenches into the conformal material layer and the insulation such that the plurality of trenches exposes surfaces of the plurality of fins and the semiconductor substrate;
forming a gate dielectric layer within the plurality of trenches;
depositing a barrier metal layer overlying the gate dielectric layer;
forming a work function layer overlying the gate dielectric layer;
depositing a conductive gate overlying the work function layer;
recessing the gate dielectric layer, the barrier metal layer, the work function layer, and the conductive gate within the plurality of trenches;
forming an insulating cap overlying the conductive gate and within the plurality of trenches;
removing the conformal material layer; and
forming spacers on sidewalls of the conductive gate.
